(19) United States
(12) Patent Application Publication
(10) Pub. No.: US 2024/0401888 A1
(43) Pub. Date: Dec. 5, 2024

(54) Radiator and Connector

(71) Applicants: Tyco Electronics (Zhuhai) Ltd, Zhuhai (CN); Tyco Electronics (Shanghai) Co., Ltd., Shanghai (CN)

(72) Inventors: Tao Peng, Shanghai (CN); Qing Zhong, Zhuhai (CN); Jikang Wei, Zhuhai (CN); Guangming (Suny) Zhao, Shanghai (CN); WenYu (Vindy) Liu, Shanghai (CN); Ming (Micky) Jiang, Zhuhai (CN)

(73) Assignees: Tyco Electronics (Zhuhai) Ltd, Zhuhai (CN); Tyco Electronics (Shanghai) Co., Ltd., Shanghai (CN)

(21) Appl. No.: 18/678,739

(22) Filed: May 30, 2024

(30) Foreign Application Priority Data
Jun. 1, 2023 (CN) 202310644701.8

(51) Int. Cl. F28F 3/04; F28F 9/26; H01R 13/533

(52) U.S. Cl. CPC F28F 3/048; F28F 9/268; H01R 13/533

(57) ABSTRACT

A radiator includes a seat having top and bottom surfaces opposite to each other in a height direction of the radiator. A fin heat sink is welded to the top surface of the seat. The fin heat sink is an integral stamped part formed by stamping a single sheet of material plate.

### CROSS-REFERENCE TO RELATED APPLICATION

This application claims the benefit of Chinese Patent Application No. CN 202310644701.8 filed on Jun. 1, 2023, in the State Intellectual Property Office of China, the whole disclosure of which is incorporated herein by reference.

### FIELD OF THE INVENTION

Embodiments of the present disclosure relate to a radiator and a connector comprising the radiator.

### BACKGROUND

In the prior art, a high-performance radiator for a connector typically includes a seat and a fin heat sink. The fin heat sink is welded to the top surface of the seat. The fin heat sink usually has a stamped fin chain structure. During manufacturing, multiple heat dissipation fins are first processed, and then stacked and riveted together. The seat is usually a machined part. In the prior art, the stacking and riveting process of multiple heat dissipation fins is complex, with a high scrap rate. This leads to higher costs and manufacturing times. In addition, the cost of a machined seat is also relatively high.

### SUMMARY

According to an embodiment of the present disclosure, a radiator includes a seat having top and bottom surfaces opposite to each other in a height direction of the radiator. A fin heat sink is welded to the top surface of the seat. The fin heat sink is an integral stamped part formed by stamping a single sheet of material plate.

### BRIEF DESCRIPTION OF THE DRAWINGS

The invention will now be described by way of example with reference to the accompanying Figures, of which:

FIG. 1 shows an illustrative perspective view of a radiator according to an exemplary embodiment of the present invention when viewed from the top;

FIG. 2 shows an illustrative perspective view of a radiator according to an exemplary embodiment of the present invention when viewed from the bottom;

FIG. 3 shows an illustrative exploded view of a radiator according to an exemplary embodiment of the present invention;

FIG. 4 shows an illustrative perspective view of a fin heat sink of a radiator according to an exemplary embodiment of the present invention;

FIG. 5 shows an illustrative exploded view of a seat of a radiator according to an exemplary embodiment of the present invention when viewed from the top;

FIG. 6 shows an illustrative perspective view of a seat of a radiator according to an exemplary embodiment of the present invention when viewed from the top; and

FIG. 7 shows an illustrative perspective view of a seat of a radiator according to an exemplary embodiment of the present invention when viewed from the bottom.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth to provide a thorough understanding of the disclosed embodiments. It will be apparent, however, that one or more embodiments may be practiced without these specific details. In other instances, well-known structures and devices are schematically shown to simplify the drawing.

A radiator according to an embodiment of the present disclosure includes a seat having top and bottom surfaces opposite to each other in a height direction of the radiator, and a fin heat sink welded to the top surface of the seat. The fin heat sink is an integral stamped part formed by stamping a single sheet of material plate.

According to another embodiment, a radiator a seat and a fin heat sink which is welded to the top surface of the seat. The seat includes a frame and a base which is installed into the frame. At least one of the frame, the base and the fin heat sink is an integral stamped part.

According to another embodiment, a connector includes a connector housing and the above radiator installed on the connector housing. The bottom of the seat of the radiator protrudes into the connector housing through an opening on the connector housing for thermal contacting with a heat generating component inside the connector housing.

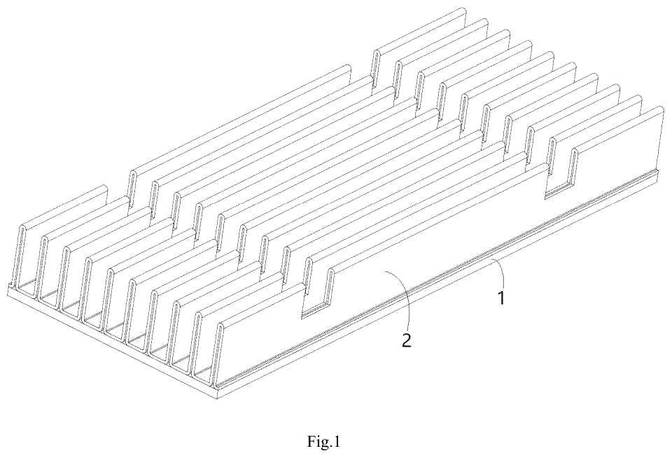

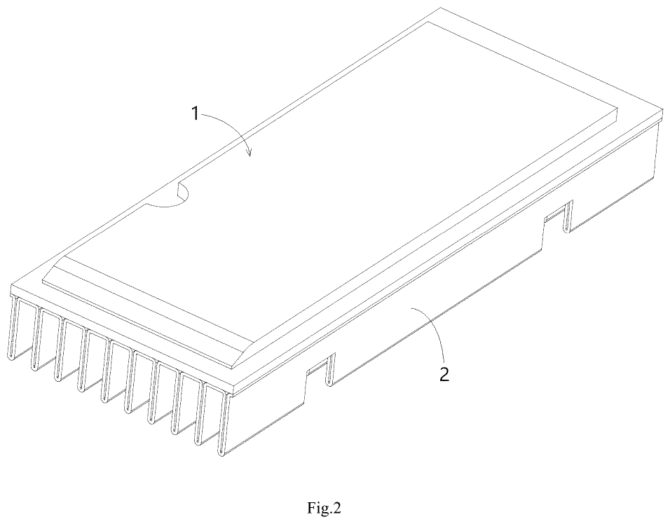

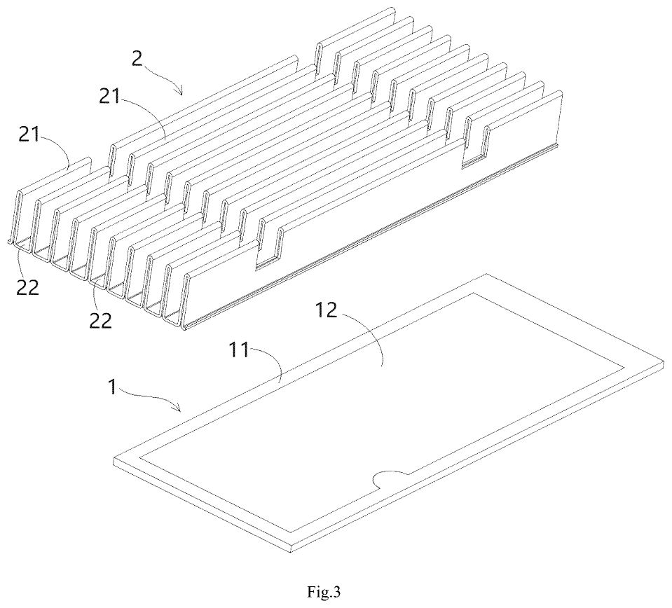

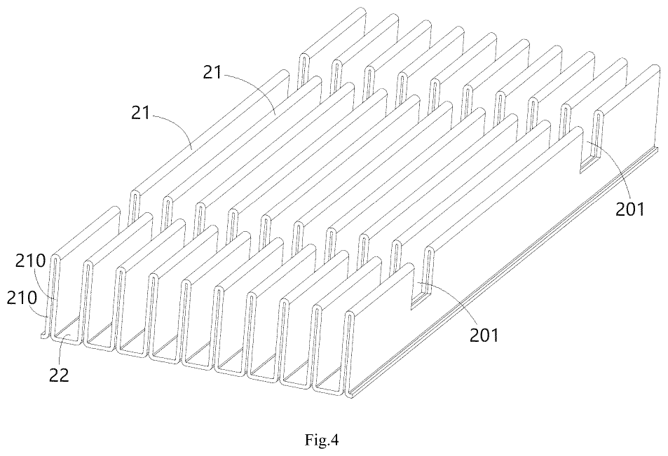

FIG. 1 shows an illustrative perspective view of a radiator according to an exemplary embodiment of the present invention when viewed from the top. FIG. 2 shows an illustrative perspective view of a radiator according to an exemplary embodiment of the present invention when viewed from the bottom. FIG. 3 shows an illustrative exploded view of a radiator according to an exemplary embodiment of the present invention. FIG. 4 shows an illustrative perspective view of a fin heat sink of a radiator according to an exemplary embodiment of the present invention.

As shown in FIGS. 1-4, in an exemplary embodiment of the present invention, a radiator is disclosed. The radiator includes a seat 1 and a fin heat sink 2. The seat 1 has top and bottom surfaces opposite to each other in the height direction Z of the radiator. The fin heat sink 2 is welded to the top surface of the seat 1. In the illustrated embodiment, the fin heat sink 2 is an integral stamped part formed by stamping a single sheet of material plate. Therefore, the fin heat sink 2 can be unfolded into a single sheet of material plate. In this way, the manufacturing cost of the radiator can be reduced, while also greatly improving the manufacturing efficiency of the radiator.

The fin heat sink 2 includes multiple heat dissipation fins 21 arranged side by side and multiple bottom connection strips 22 arranged side by side. Multiple heat dissipation fins 21 and multiple bottom connection strips 22 are arranged alternately. The bottom connection strip 22 is connected between the bottom of adjacent heat dissipation fins 21. Multiple heat dissipation fins 21 extend along the longitudinal direction Y and the height direction Z of the radiator and are arranged side by side in the transverse direction X of the radiator. Multiple bottom connection strips 22 extend along the transverse direction X and the longitudinal direction Y of the radiator and are arranged side by side in the transverse direction X of the radiator.

The heat dissipation fin 21 includes two layers of side plates 210 stacked together, so that the heat dissipation fin 21 has a double-layer plate structure. The bottom connection strip 22 has a single-layer plate structure and is connected between the bottom of two side plates 210 facing each other of adjacent heat dissipation fins 21. Multiple bottom connection strips 22 form the bottom wall of the fin heat sink 2, and multiple bottom connection strips 22 are welded to the top surface of the base 1.

In the illustrated embodiments, an installation slot 201 is formed on multiple heat dissipation fins 21 for installing an elastic clip (not shown), so that the fin heat sink 2 can be fixed to the connector housing (not shown) by the elastic clip. In the illustrated embodiment, the installation slot 201 extends along the transverse direction X of the radiator and runs through multiple heat dissipation fins 21.

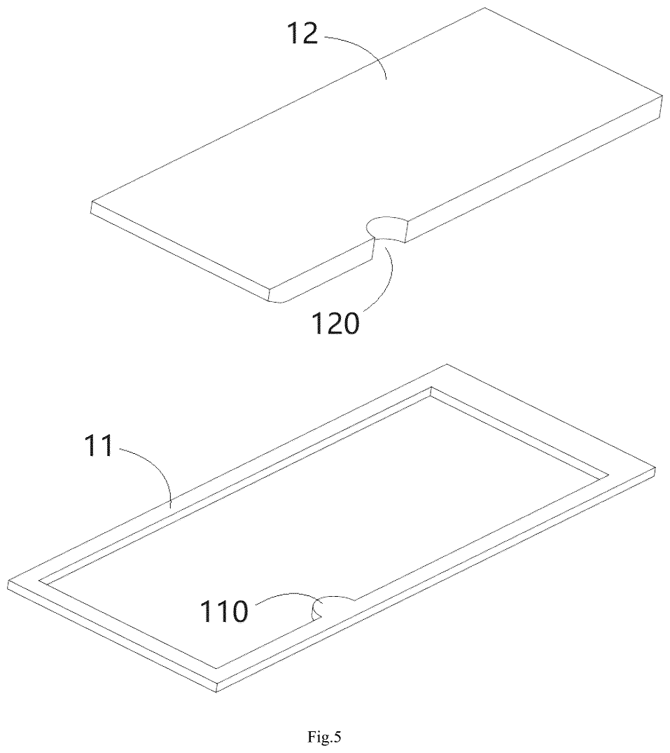

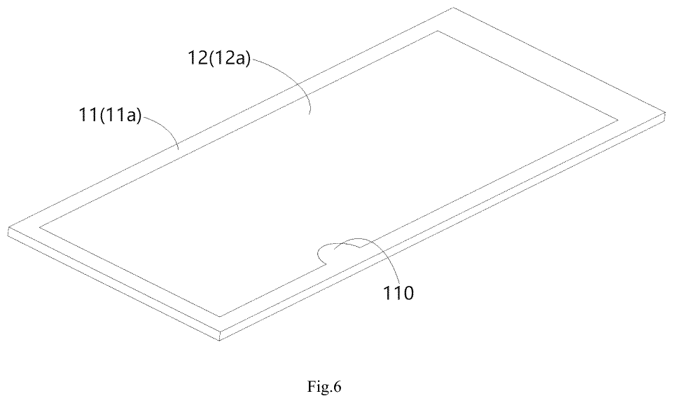

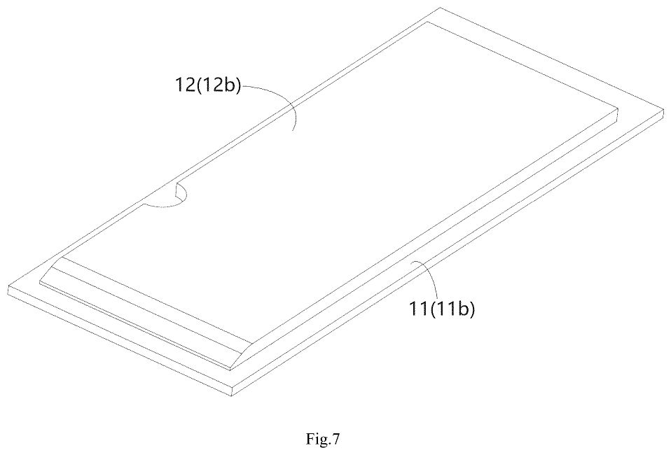

FIG. 5 shows an illustrative exploded view of the seat 1 of the radiator according to an exemplary embodiment of the present invention when viewed from the top. FIG. 6 shows an illustrative perspective view of the seat 1 of a radiator according to an exemplary embodiment of the present invention when viewed from the top. FIG. 7 shows an illustrative perspective view of the seat 1 of a radiator according to an exemplary embodiment of the present invention when viewed from the bottom.

As shown in FIGS. 1 to 7, in the illustrated embodiments, the seat 1 comprises a frame 11 and a base 12. The base 12 is installed in the frame 11. In the illustrated embodiment, each of the frame 11 and the base 12 is an integral stamped part. The base 12 is riveted into the frame 11, so that the base 12 and the frame 11 are fixed together. In the illustrated embodiment, the frame 11 and the base 12 can be directly riveted together in a stamping die for forming them, thereby eliminating the need for a separate riveting tool, and further reducing manufacturing costs.

The top surface 11a of the frame 11 and the top surface 12a of the base 12 are located in the same plane. The fin heat sink 2 is welded to the top surfaces 11a and 12a of the frame 11 and the base 12. The bottom of the base 12 protrudes at a predetermined height from the bottom surface 11b of the frame 11. The bottom surface 11b of the frame 11 is adapted to be positioned on the outer side of the connector housing, and the bottom of the base 12 is adapted to protrude into the interior of the connector housing through an opening on the connector housing to make thermal contact with a heat generating component (not shown, for example, a terminal assembly) inside the connector housing.

In the illustrated embodiments, the base 12 has a flat contact bottom surface 12b, which is used for thermal contact with the heat generating component inside the connector housing. A semi-circular positioning protrusion 110 is formed on the inner side surface of the frame 11, and a semi-circular positioning recess 120 is formed on the outer surface of the base 12. The semi-circular positioning protrusion 110 is used to fit with the semi-circular positioning recess 120 to ensure that the frame 11 and the base 12 are installed together in the correct orientation.

Still referring to FIGS. 1-7, in another exemplary embodiment of the present invention, a radiator includes a seat 1 and a fin heat sink 2. The fin heat sink 2 is welded to the top surface of the base 1. The seat 1 includes a frame 11 and a base 12. The base 12 is installed into the frame 11. In the illustrated embodiment, at least one of the aforementioned frame 11, base 12 and fin heat sink 2 is an integral stamped part.

In another exemplary embodiment of the present invention, a connector is also disclosed. The connector includes: a connector housing; a heat generating component (such as a terminal assembly) which is installed or inserted in the connector housing; and the above radiator which is installed on the connector housing. The bottom of the seat 1 of the radiator protrudes into the connector housing through an opening on the connector housing and comes into thermal contact with the heat generating component.

In addition, those areas in which it is believed that those of ordinary skill in the art are familiar, have not been described herein in order not to unnecessarily obscure the invention described. Accordingly, it must be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A radiator, comprising:
a seat having top and bottom surfaces opposite to each other in a height direction of the radiator; and
a fin heat sink welded to the top surface of the seat, the fin heat sink is an integral stamped part formed by stamping a single sheet of material plate.

2. The radiator according to claim 1, wherein the fin heat sink comprises multiple heat dissipation fins arranged side by side and multiple bottom connection strips arranged side by side.

3. The radiator according to claim 2, wherein the multiple heat dissipation fins and the multiple bottom connection strips are alternately arranged, and the bottom connection strip is connected between the bottom of adjacent two heat dissipation fins.

4. The radiator according to claim 3, wherein the multiple heat dissipation fins extend along a longitudinal direction and the height direction of the radiator and are arranged side by side in a transverse direction of the radiator.

5. The radiator according to claim 4, wherein the multiple bottom connection strips extend along the transverse direction and the longitudinal direction of the radiator and are arranged side by side in the transverse direction of the radiator.

6. The radiator according to claim 3, wherein the heat dissipation fin includes two stacked side plates, so that the heat dissipation fin has a double-layer plate structure.

7. The radiator according to claim 6, wherein the bottom connection strip has a single-layer plate structure, and the bottom connection strip is connected between the bottom of two side plates facing each other of adjacent heat dissipation fins.

8. The radiator according to claim 3, wherein the multiple bottom connection strips constitute the bottom wall of the fin heat sink, and the multiple bottom connection strips are welded to the top surface of the seat.

9. The radiator according to claim 3, wherein an installation slot is formed on the multiple heat dissipation fins for installing an elastic clip, so that the fin heat sink can be fixed to a connector housing by the elastic clip.

10. The radiator according to claim 9, wherein the installation slot extends along the transverse direction of the radiator and runs through the multiple heat dissipation fins.

11. The radiator according to claim 1, wherein the seat comprises:
a frame; and
a base which is installed in the frame, each of the frame and the base is an integral stamped part.

12. The radiator according to claim 11, wherein the base is riveted into the frame, so that the base and the frame are fixed together.

13. The radiator according to claim 12, wherein the frame and the base are directly riveted together in a stamping die for forming them.

14. The radiator according to claim 11, wherein the top surfaces of the frame and the base are located in the same plane, and the fin heat sink is welded to the top surfaces of the frame and the base.

15. The radiator according to claim 11, wherein the bottom of the base protrudes at a predetermined height from the bottom surface of the frame, and the bottom surface of the frame is adapted to be positioned on the outer side of the connector housing.

16. The radiator according to claim 15, wherein the bottom of the base is adapted to protrude into the interior of the connector housing through an opening on the connector housing to make thermal contact with a heat generating component inside the connector housing.

17. The radiator according to claim 16, wherein the base has a flat contact bottom surface, which is used for thermal contact with the heat generating component inside the connector housing.

18. The radiator according to claim 11, wherein a semi-circular positioning protrusion is formed on the inner side surface of the frame, and a semi-circular positioning recess is formed on the outer side surface of the base.

19. The radiator according to claim 18, wherein the semi-circular positioning protrusion is used to fit with the semi-circular positioning recess to ensure that the frame and the base are installed together in a correct orientation.

20. A radiator, comprising:
a seat, including:
a frame; and
a base which is installed into the frame; and
a fin heat sink which is welded to the top surface of the seat, wherein at least one of the frame, the base and the fin heat sink is an integral stamped part.
